(19) United States
(12) Patent Application Publication
(10) Pub. No.: US 2017/0194592 A1
(43) Pub. Date: Jul. 6, 2017

(54) Flexible Display Panel, Stress-Chromism Polymer and its Manufacturing Method

(71) Applicants: BOE Technology Group Co., Ltd., Beijing (CN); Hefei BOE Optoelectronics Technology Co., Ltd., Anhui (CN)

(72) Inventors: Shengchao Jiang, Beijing (CN); Kun Yu, Beijing (CN); Yusheng An, Beijing (CN)

(21) Appl. No.: 15/212,894

(22) Filed: Jul. 18, 2016

(30) Foreign Application Priority Data
Jan. 5, 2016 (CN) 201610005343.6

(51) Int. Cl. H01L 51/52; H01L 51/00; H01L 51/56

(52) U.S. Cl. CPC H01L 51/52; H01L 51/56; H01L 51/0035; H01L 51/0097; H01L 51/0043; H01L 2251/5338; H01L 2251/558

(57) ABSTRACT

An organic light emitting diode flexible display panel and its manufacturing method, a flexible display apparatus and a manufacturing method for a stress-chromism polymer are provided. The flexible display panel includes: a flexible substrate; a warning layer provided on the flexible substrate and capable of changing color according to its own deformation amount. The warning layer can change its color according to its own deformation amount.

This application claims priority to and the benefit of Chinese Patent Application No. 201610005343.6 filed on Jan. 5, 2016, which application is incorporated herein in its entirety.

### TECHNICAL FIELD

The embodiments of the present disclosure relate to an organic light emitting diode flexible display panel, a flexible display apparatus, a manufacturing method for a stress-chromism polymer, and a manufacturing method for an organic light emitting diode flexible display panel.

### BACKGROUND

A flexible organic light emitting diode (OLED) is significantly advantageous over a conventional display screen. Compared with the conventional display screen, the flexible organic light emitting diode not only has a slimmer volume and lower power consumption, but also improves endurance ability of an apparatus. At the same time, based on its good character of flexible and ductile, it is more reliable than the existing display screen, and thus effectively lowers the probability of accident damage of the apparatus.

### SUMMARY

Embodiments of the present disclosure provide an organic light emitting diode flexible display panel, comprises: a flexible substrate; and a warning layer provided above the flexible substrate, the warning layer capable of changing color according to its own deformation amount.

In one embodiment of the present disclosure, for example, the flexible display panel further comprises: a light emitting layer provided above the flexible substrate, wherein the warning layer is provided between the light emitting layer and the flexible substrate, or the light emitting layer is provided between the warning layer and the light emitting layer.

In one embodiment of the present disclosure, for example, material of the warning layer comprises a polymer containing spiropyran.

In one embodiment of the present disclosure, for example, the polymer is a triblock polymer material including a rigid molecular chain material, a flexible molecular chain material and the spiropyran.

In one embodiment of the present disclosure, for example, the rigid molecular chain material accounts for a mass percentage larger than or equal to 25% and less than 40% of the total mass of the rigid molecular chain material and the flexible molecular chain material.

In one embodiment of the present disclosure, for example, the mass percentage of the rigid molecular chain material to the total mass of the rigid molecular chain material and the flexible molecular chain material is larger than or equal to 25% and less than or equal to 30%.

In one embodiment of the present disclosure, for example, relative molecular weight of the polymer is larger than or equal to 100,000, and less than or equal to 500,000.

In one embodiment of the present disclosure, for example, the rigid molecular chain material includes at least one of: polystyrene (PS), polyurethane (PU), polycaprolactone (PCL), and polymethylmethacrylate (PMMA).

In one embodiment of the present disclosure, for example, the flexible molecular chain material includes at least one of: poly(butyl acrylate) and poly(isobutyl acrylate).

In one embodiment of the present disclosure, for example, the warning layer has a thickness larger than or equal to 0.1 mm and less than or equal to 0.4 mm.

In one embodiment of the present disclosure, for example, the warning layer has a thickness larger than or equal to 0.24 mm and less than or equal to 0.26 mm.

Embodiments of the present disclosure also provide a flexible display apparatus including the above organic light emitting diode flexible display panel.

Embodiments of the present disclosure also provide a manufacturing method for a stress-chromism polymer, includes: blending and uniformly stirring a flexible molecular chain material and an initiator containing spiropyran; adding a catalyst and a synergist; in a hermetic environment in a preset temperature range, stirring for a first preset time period in oil bath, obtaining a polymerization product of the spiropyran and the flexible molecular chain material; adding a rigid molecular chain material into the polymerization product of the spiropyran and the flexible molecular chain material and stirring uniformly; adding a catalyst and a synergist; in a hermetic environment in a preset temperature range, stirring for a second preset time period in oil bath, obtaining a triblock polymer including the rigid molecular chain material, the flexible molecular chain material and the spiropyran.

In one embodiment of the present disclosure, for example, in the manufacturing method for a stress-chromism polymer, adding the rigid molecular chain material into the polymerization product of the spiropyran and the flexible molecular chain material and stirring uniformly includes: adding the rigid molecular chain material into the polymerization product of the spiropyran and the flexible molecular chain material so that the rigid molecular chain material accounts for a mass percentage larger than or equal to 25% and less than 40% of the total mass of the rigid molecular chain material and the flexible molecular chain material.

In one embodiment of the present disclosure, for example, in the manufacturing method for a stress-chromism polymer, the mass percentage of the rigid molecular chain material to the total mass of the rigid molecular chain material and the flexible molecular chain material is larger than or equal to 25% and less than or equal to 30%.

In one embodiment of the present disclosure, for example, in the manufacturing method for a stress-chromism polymer, the first preset time period is 10 to 12 hours.

In one embodiment of the present disclosure, for example, in the manufacturing method for a stress-chromism polymer, the second preset time period is 10 to 15 hours.

In one embodiment of the present disclosure, for example, in the manufacturing method for a stress-chromism polymer, the rigid molecular chain material includes at least one of: polystyrene (PS), polyurethane (PU), polycaprolactone (PCL), and polymethylmethacrylate (PMMA).

In one embodiment of the present disclosure, for example, in the manufacturing method for a stress-chromism polymer, the rigid molecular chain material includes at least one of: poly(butyl acrylate) and poly(isobutyl acrylate).

In one embodiment of the present disclosure, for example, in the manufacturing method for a stress-chromism polymer, the preset temperature range is 50° C. to 100° C.

In one embodiment of the present disclosure, for example, in the manufacturing method for a stress-chromism polymer, the hermetic environment is formed by at least one of the following gas: nitrogen, helium, neon and argon.

Embodiments of the present disclosure also provide a manufacturing method for an organic light emitting diode flexible display panel includes: forming a light emitting layer on a flexible substrate; forming a warning layer utilizing the stress-chromism polymer obtained by the above manufacturing method, between the flexible substrate and the light emitting layer, or above the light emitting layer.

In one embodiment of the present disclosure, for example, forming the warning layer includes: forming the early warning having a thickness larger than or equal to 0.1 mm and less than or equal to 0.4 mm.

In one embodiment of the present disclosure, for example, forming the warning layer includes: forming the warning layer having a thickness larger than or equal to 0.24 mm and less than or equal to 0.26 mm.

In one embodiment of the present disclosure, for example, the warning layer having the corresponding thickness is formed by controlling a feeding amount of the polymer material.

In one embodiment of the present disclosure, for example, forming the warning layer includes: curing the polymer material coated between the flexible substrate and the light emitting layer or coated above the light emitting layer for 29 to 31 minutes at a temperature between 95° C. to 105° C.

In one embodiment of the present disclosure, for example, forming the warning layer includes: curing the polymer material coated between the flexible substrate and the light emitting layer or coated above the light emitting layer for 30 minutes at 100° C.

### BRIEF DESCRIPTION OF THE DRAWINGS

In order to clearly illustrate the technical solution of the embodiments of the disclosure, the drawings of the embodiments will be briefly described in the following, it is obvious that the described drawings are only related to some embodiments of the disclosure and thus are not limitative of the disclosure.

FIG. 1 is a schematic diagram showing structure of an organic light emitting diode flexible display panel according to an embodiment of the present invention;

FIG. 2 is a schematic diagram showing structure of an organic light emitting diode flexible display panel according to another embodiment of the present invention; and

FIG. 3 is a schematic flowchart diagram showing a manufacturing method for a stress-chromism polymer according to an embodiment of the present invention.

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

Flexible display is always been focused since it is invented, and will also be a developing trend of the future display technology. A flexible display material can generate large deformation. However, the deformation will become invertible when exceeding a certain limit, and as a result, the material may be damaged.

In order to avoid the excessive deformation, a flexible OLED has been proposed. In this OLED, a composite material based on polyethylene terephthalate (PET) capable of sensing variation of stress is incorporated. The PET-based composite material includes a conductive phase function component and a PET-based material. Wherein the conductive phase function component accounts for 6% to 80% by mass of the PET-based material. The PET-based material having the conductive function is capable of converting a mechanical response into an electric signal, and the mechanical response can be back calculated from variation of electric performance parameters, and thus the object of monitoring stress/strain can be achieved. With the above solution, early-warning effects can be obtained. However, in the above structure, because the organic light emitting material does not have early warning function by itself, devices such as sensors should be incorporated to realize the early-warning function, and thus the early warning structure is complex.

As shown in FIG. 1, an organic light emitting diode flexible display panel according to an embodiment of the present invention includes a flexible substrate 1 and a warning layer 2 provided on the flexible substrate 1 and capable of changing color according to its own deformation amount.

In the present embodiment, the warning layer 2 is capable of changing color according to its own deformation amount. Therefore, when the flexible display panel is bent, the warning layer 2 can gradually change its color as the deformation amount generated by bending is increasing, and thus the deformation degree of the flexible display panel can be remarkably noticed by a user. In the present embodiment, the early warning effect is produced by changing color according to the deformation amount, thus it can be achieved only by the warning layer 2 itself, and as a result, the structure is simplified.

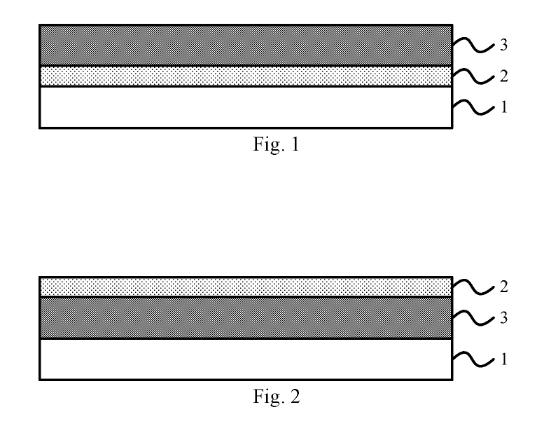

For example, the above display panel further includes a light emitting layer 3 provided on the flexible substrate 1. The warning layer 2 is provided between the light emitting layer 3 and the flexible substrate 1 (as shown in FIG. 1), or is provided above the light emitting layer 3 (as shown in FIG. 2). The light emitting layer 3 may include layer structures, such as a hole injection layer, a hole transportation layer, an organic light emitting layer, an electron transportation layer, an electron injection layer, and so on. The proper position of the warning layer 2 can be provided as necessary. Of course, other layer structures, e.g. a protection substrate, a touch circuit, and so on can also be provided above the light emitting layer 3.

For example, material for the warning layer is a polymer including spiropyran.

The polymer of the spiropyran, e.g. colorless ring-closed spiropyran, when being subjected to stress, is capable of achieving a reversible isomerization with colorful ring-opened body anthocyanosides, and thus achieving changing color according to stress (deformation).

For example, the polymer is a triblock polymer material including a rigid molecular chain material, a flexible molecular chain material and a spiropyran.

Through the rigid molecular chain material and the flexible molecular chain material, the warning layer obtains both rigidity and flexibility and resists rupture when being bent by a certain stress, and recover to the original state after the stress is released.

For example, the rigid molecular chain material accounts for a mass percentage larger than or equal to 25% and less than 40% of the total mass of the rigid molecular chain material and the flexible molecular chain material. Table 1 shows the influence on the color changing performance of the polymer by different percentage of the rigid molecular chain material to the total mass of the rigid molecular chain material and the flexible molecular chain material.

TABLE 1
influence on the color changing performance of the polymer by different
percentage of the rigid molecular chain material to the total mass of the
rigid molecular chain material and the flexible molecular chain material.

| | | Molecular | | | Color |
|---|---|---|---|---|---|
| | | weight | PS | Modulus | changing |
| Sample | PS-PnBA-PS | Mₙ(g/mol) | (wt %) | (MPa) | performance |
| 1 | 3-30-3 | 36,000 | 17 | 216 | none |
| 2 | 5-30-5 | 40,000 | 25 | 50 | affected |
| 3 | 9-30-9 | 48,000 | 40 | 1 | unnoticeable |

In Table 1, PS (polystyrene) is used as the rigid molecular chain, and PnBA(poly(butyl acrylate)) is used as the flexible molecular chain. When the mass percentage of the rigid molecular chain material to the total mass of the rigid molecular chain material and the flexible molecular chain material is larger than or equal to 25%, and less than 40%, the warning layer exhibits force-induced-chromism property.

For example, the mass percentage of the rigid molecular chain material to the total mass of the rigid molecular chain material and the flexible molecular chain material is larger than or equal to 25%, and less than 30%. When the mass percentage of the rigid molecular chain material to the total mass of the rigid molecular chain material and the flexible molecular chain material is within this range, the force-induced-chromism performance of the warning layer is better.

For example, the relative molecular weight of the polymer is larger than or equal to 100,000, and less than or equal to 500,000. By providing the relative molecular weight of the polymer as being larger than or equal to 100,000 and less than or equal to 500,000, the mechanical performance of the warning layer can be improved.

For example, material for the rigid molecular chain includes at least one of polystyrene (PS), polyurethane (PU), polycaprolactone (PCL), and polymethylmethacrylate (PMMA).

For example, material for the flexible molecular chain includes at least one of poly(butyl acrylate) and poly(isobutyl acrylate).

For example, thickness of the warning layer is larger than or equal to 0.1 mm, and less than or equal to 0.4 mm. The table 2 shows the influence on the color changing performance by the thickness of the warning layer.

TABLE 2
influence on the color changing performance
by the thickness of the warning layer

| Film thickness | Color changing phenomenon | |
|---|---|---|
| (mm) | (200% deformation amount) | Suitable or not |
| 0.11 | unnoticeable | No |
| 0.24 | remarkable | Yes |
| 0.42 | too remarkable | No |

When the thickness of the warning layer is larger than 0.4 mm, the warning layer is excessively sensitive to the force-induced-chromism. For example, the warning layer will change its color only by force generated by contacting, rather than by being excessively bent, thus it cannot achieve the early warning effect, and also excessively increases the thickness of the display panel. When the thickness of the warning layer is less than 0.1 mm, the color changing under stress of the warning layer is too slow to be noticed by human eyes, and can not achieve the early warning effect, either. When the thickness of the warning layer is between 0.1 mm and 0.4 mm, a good color changing performance can be guaranteed.

For example, the thickness of the warning layer is larger than or equal to 0.24 mm and less than or equal to 0.26 mm. When the thickness of the warning layer is between 0.24 mm and 0.26 mm, a good performance of the warning layer is guaranteed, and a thickness of the display panel would not be excessively increased.

An embodiment of the present invention further provides a flexible display apparatus including the above-described organic light emitting diode flexible display panel.

It is to be noted that the flexible display apparatus in the present embodiment can be an electronic paper, a mobile phone, a tablet computer, a navigator, or any other product or component having display function.

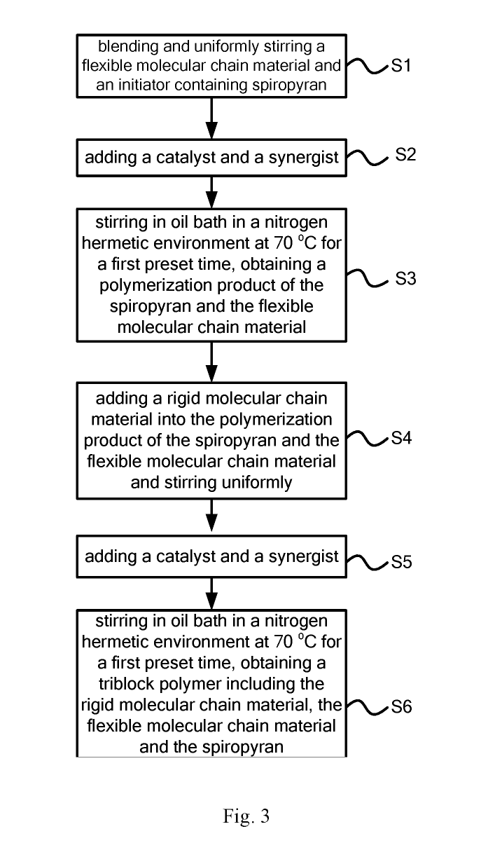

As shown in FIG. 3, an embodiment of the present invention further provides a manufacturing method for a stress-chromism polymer, including:

S1, blending and stirring uniformly a flexible molecular chain material and an initiator including spiropyran;

S2, adding a catalyst and a synergist;

S3, in a hermetic environment in a preset temperature range, by stirring for a first preset time period in oil bath, obtaining a polymer of the spiropyran and a flexible molecular chain material;

S4, adding a rigid molecular chain material into the polymerization product of the spiropyran and the flexible molecular chain material, and stirring uniformly;

S5, adding a catalyst and a synergist;

S6, in a hermetic environment in a preset temperature range, by stirring for a second preset time period in oil bath, obtaining a triblock polymer of the rigid molecular chain, the flexible molecular chain and the spiropyran.

In the present embodiment, the triblock polymer material including the rigid molecular chain material, the flexible molecular chain material and the spiropyran is formed as the stress-chromism polymer. The initiator including the spiropyran can be Br-SP-Br (spiropyran bromine), the catalyst may be copper bromine, and the synergist may be 2,2-bipyridine. The obtained polymerization product of the spiropyran and the flexible molecular chain material may be weighted by subtraction method. Every kind of materials may be configured according to the mole ratio as shown in Table 3.

TABLE 3
mole ratio of the reactants

| Solution | Mole ratio |
|---|---|
| Br—SP—Br (spiropyran bromine) | 1 |
| nBA (Butyl acrylate) | 280 |
| Styrene | 160 |
| Catalyst (copper bromine) | 3 |
| Synergist (2,2-bipyridine) | 3 |
| Solvent (methylbenzene) | 85 |

In step S4, adding the rigid molecular chain material into the polymerization product of the spiropyran and the flexible molecular chain material can include adding methylbenzene and styrene in the polymerization product of the spiropyran and the flexible molecular chain material (to form polystyrene as the rigid molecular chain) and stirring uniformly.

For example, adding the rigid molecular chain material into the polymerization product of the spiropyran and the flexible molecular chain material and stirring uniformly includes adding the rigid molecular chain material into the polymerization product of the spiropyran and the flexible molecular chain material so that the rigid molecular chain material accounts for a mass percentage larger than or equal to 25% and less than 40% of the total mass of the rigid molecular chain material and the flexible molecular chain material.

For example, the mass percentage of the rigid molecular chain material to the total mass of the rigid molecular chain material and the flexible molecular chain material is larger than or equal to 25% and less than or equal to 30%.

For example, the first preset time period is from 10 to 12 hours. By stirring in oil bath in a nitrogen hermetic environment at 70° C. for 10 to 12 hours, the initiator of the spiropyran and the flexible molecular chain material can thoroughly react.

For example, the second preset time period is from 10 to 15 hours. By stirring in oil bath in a nitrogen hermetic environment at 70° C. for 10 to 15 hours, the triblock polymer material including the rigid molecular chain material, the flexible molecular chain material and the spiropyran can be obtained to have a relative molecular weight larger than or equal to 100,000 and less than or equal to 500,000, to improve the mechanical performance of the warning layer, for example, resistance to fracture.

For example, the material for the rigid molecular chain includes at least one of polystyrene (PS), polyurethane (PU), polycaprolactone (PCL), and polymethylmethacrylate (PMMA).

For example, when the rigid molecular chain material is polystyrene (PS), adding the rigid molecular chain material into the polymerization product of the spiropyran and the flexible molecular chain material and stirring uniformly includes adding methylbenzene and polystyrene into the polymerization product of the spiropyran and the flexible molecular chain material and stirring uniformly.

For example, the rigid molecular chain material includes at least one of poly(butyl acrylate) and poly(isobutyl acrylate).

For example, the preset temperature range is 50° C. to 100° C.

By controlling the reaction temperature in this range, a relative fast reaction speed at which the materials react in the solvent can be ensured, meantime, the materials in the solvent would not be decomposed due to high temperature, and thus the desire polymer material can be obtained.

For example, the hermetic environment can be formed by at least one of nitrogen gas, helium gas, neon gas and argon gas. Of course, other inert gas can also be used to form the hermetic environment, and thus the materials in the solvent are prevented from oxidation during reaction.

An embodiment of the present invention further provides a manufacturing method for an organic light emitting diode flexible display panel including forming a light emitting layer on a flexible substrate; forming a warning layer by the above described triblock polymer material between the flexible substrate and the light emitting layer or above the light emitting layer.

For example, forming the warning layer includes: forming the warning layer having thickness larger than or equal to 0.1 mm and less than or equal to 0.4 mm.

For example, forming the warning layer includes forming the warning layer having thickness larger than or equal to 0.24 mm and less than or equal to 0.26 mm.

For example, the warning layer with the corresponding thickness is formed by controlling a feeding amount of the polymer material. For example, the material for the flexible substrate is PET, and has a size of 0.8 m multiple 1.0 m, then the feeding amount can be controlled to 100 ml per substrate to 350 ml per substrate, thus such formed warning layer has a thickness larger than or equal to 0.1 mm and less than and equal to 0.4 mm.

For example, forming the warning layer includes curing the polymer material coated between the flexible substrate and the light emitting layer or coated above the light emitting layer at a temperature from 95° C. to 105° C. for 29 to 31 minutes. By curing for the above described time period at the above temperature, it ensures that the warning layer can be well cured.

For example, forming the warning layer includes curing the polymer material coated between the flexible substrate and the light emitting layer or above the light emitting layer for 30 minutes at 100° C. With the present embodiment, it ensures that the warning layer can be well cured.

Wherein, the forming method employed in the above process, for example, may include filming process such as deposition, sputtering, etc. and patterning process such as etching, etc.

The technical solution of the embodiments of the present invention has been described above with reference to the attached drawings. In the conventional technology, the organic light emitting material does not has the warning function, and the force induced color changing warning function of the flexible display panel is achieved by means of a device such as a sensor, resulting in a complex warning structure. In the technical solution provided by the embodiments of the present invention, the warning layer can change its color according to its own deformation amount. Therefore, when the flexible display panel is bent, the warning layer can change its color gradually as the deformation amount generated by bending is increased, and thus the user can remarkably notice the deformation degree of the flexible display panel. In the technical solution provided by the embodiments of the present invention, the warning layer can give warning by changing color according to its deformation amount. Only the warning layer itself is needed to achieve the early warning function, and therefore the early-warning-structure is simplified.

What are described above is related to the illustrative embodiments of the disclosure only and not limitative to the scope of the disclosure; the scopes of the disclosure are defined by the accompanying claims.

The present application claims the priority of the Chinese Patent Application

No. 201610005343.6 filed on Jan. 5, 2016, which is incorporated herein by reference as part of the disclosure of the present application.

1. An organic light emitting diode flexible display panel, comprising:
a flexible substrate; and
a warning layer provided above the flexible substrate, the warning layer capable of changing color according to its own deformation amount.

2. The flexible display panel according to claim 1, further comprising:
a light emitting layer provided above the flexible substrate,
wherein the warning layer is provided between the light emitting layer and the flexible substrate, or the light emitting layer is provided between the warning layer and the light emitting layer.

3. The flexible display panel according to claim 1, wherein a material of the warning layer comprises a polymer containing spiropyran.

4. The flexible display panel according to claim 3, wherein the polymer is a triblock polymer material including a rigid molecular chain material, a flexible molecular chain material and the spiropyran.

5. The flexible display panel according to claim 4, wherein the rigid molecular chain material accounts for a mass percentage larger than or equal to 25% and less than 40% of a total mass of the rigid molecular chain material and the flexible molecular chain material.

6. The flexible display panel according to claim 5, wherein the mass percentage of the rigid molecular chain material to the total mass of the rigid molecular chain material and the flexible molecular chain material is larger than or equal to 25% and less than or equal to 30%.

7. The flexible display panel according to claim 4, wherein a relative molecular weight of the polymer is larger than or equal to 100,000, and less than or equal to 500,000.

8. The flexible display panel according to claim 4, wherein the rigid molecular chain material includes at least one selected from the group consisting of:
polystyrene (PS), polyurethane (PU), polycaprolactone (PCL), and polymethylmethacrylate (PMMA).

9. The flexible display panel according to claim 4, wherein the flexible molecular chain material includes at least one selected from the group consisting of:
poly(butyl acrylate) and poly(isobutyl acrylate).

10. The flexible display panel according to claim 4, wherein the warning layer has a thickness larger than or equal to 0.1 mm and less than or equal to 0.4 mm.

11. The flexible display panel according to claim 1, wherein the warning layer has a thickness larger than or equal to 0.24 mm and less than or equal to 0.26 mm.

12. A flexible display apparatus including the organic light emitting diode flexible display panel according to claim 1.

13. A manufacturing method for a stress-chromism polymer, comprising:
blending and stirring a flexible molecular chain material and an initiator containing spiropyran;
adding a catalyst and a synergist;
in a hermetic environment in a preset temperature range, stirring for a first preset time period in oil bath, obtaining a polymerization product of the spiropyran and the flexible molecular chain material;
adding a rigid molecular chain material into the polymerization product of the spiropyran and the flexible molecular chain material and stirring uniformly;
adding a catalyst and a synergist; and
in a hermetic environment in a preset temperature range, stirring for a second preset time period in oil bath, obtaining a triblock polymer including the rigid molecular chain material, the flexible molecular chain material and the spiropyran.

14. The method according to claim 13, wherein adding the rigid molecular chain material into the polymerization product of the spiropyran and the flexible molecular chain material and stirring uniformly includes:
adding the rigid molecular chain material into the polymerization product of the spiropyran and the flexible molecular chain material so that the rigid molecular chain material accounts for a mass percentage larger than or equal to 25% and less than 40% of the total mass of the rigid molecular chain material and the flexible molecular chain material.

15. The method according to claim 14, wherein the mass percentage of the rigid molecular chain material to the total mass of the rigid molecular chain material and the flexible molecular chain material is larger than or equal to 25% and less than or equal to 30%.

16. The method according to claim 13, wherein the first preset time period is from 10 to 12 hours.

17. The method according to claim 13, wherein the second preset time period is from 10 to 15 hours.

18. The method according to claim 13, wherein the rigid molecular chain material includes at least one selected from the group consisting of:
polystyrene (PS), polyurethane (PU), polycaprolactone (PCL), and polymethylmethacrylate (PMMA).

19. The method according to claim 13, wherein the rigid molecular chain material includes at least one selected from the group consisting of:
poly(butyl acrylate) and poly(isobutyl acrylate).

20. The method according to claim 13, wherein the preset temperature range is from 50° C. to 100° C.
